(19) United States
(12) Patent Application Publication
(10) Pub. No.: US 2025/0112566 A1
(43) Pub. Date: Apr. 3, 2025

(54) MOTOR DRIVING DEVICE AND MOTOR DRIVING METHOD

(71) Applicant: LG INNOTEK CO., LTD., Seoul (KR)

(72) Inventors: In Seok LIM, Seoul (KR); Kun Min LEE, Seoul (KR)

(73) Assignee: LG INNOTEK CO., LTD., Seoul (KR)

(21) Appl. No.: 18/726,363

(22) PCT Filed: Jan. 3, 2023
(86) PCT No.: PCT/KR2023/000107

§ 371 Date: Jul. 2, 2024

(30) Foreign Application Priority Data
Jan. 3, 2022 (KR) 10-2022-0000599
Jan. 5, 2022 (KR) 10-2022-0001751

(51) Int. Cl. H02P 6/16; G01R 31/34; G01R 33/07; H02P 29/024

(52) U.S. Cl. CPC H02P 6/16; G01R 31/34; G01R 33/072; H02P 29/024

(57) ABSTRACT

A motor driving device according to one embodiment of the present invention comprises: a first position detection sensor for detecting the position of a motor and self-diagnosing a defect; a second position detection sensor for detecting the position of the motor; and a control unit for receiving a position signal and a self-diagnosis signal from the first position detection sensor and receiving a position signal from the second position detection sensor, wherein the control unit determines whether the first position detection sensor is normal according to the defect self-diagnosis signal and, if the first position detection sensor is normal, determines whether the second position detection sensor is defective by using the position signal of the first position detection sensor.

### TECHNICAL FIELD

The present invention relates to a motor driving device and a motor driving method, and more particularly to a motor driving device and a motor driving method for determining a defect using a different type of position detection sensor, and to a motor driving device and a motor driving method for determining a defect of a Hall sensor using a sensing voltage of the Hall sensor.

### BACKGROUND ARTS

A device (hereinafter referred to as “motor driving device”) that drives a BLDC motor (Brush-Less Direct Current motor) detects the position of the rotor through a sensor embedded in the BLDC motor (hereinafter referred to as “motor”) and supplies a three-phase AC signal to the three-phase stator winding of the BLDC motor based on the position of the rotor.

The position of the rotor is detected using a Hall sensor or the like, and the position signal detected by the Hall sensor is used to calculate the exact position of the motor, and based on this, the position of the motor is changed or the speed is controlled.

In order to increase the reliability of motor control, it is necessary to verify the position signal. A technology that can perform verification of the position signal is required.

### DETAILED DESCRIPTION OF INVENTION

### Technical Subject

The technical problem to be solved by the present invention is to provide a motor driving device and a motor driving method for determining a defect (fault) using different types of position detection sensors, and to provide a motor driving device and a motor driving method for determining a defect of a Hall sensor using a sensing voltage of the Hall sensor.

### Technical Solution

A motor driving device according to a first exemplary embodiment of the present invention comprises: a first position detection sensor for detecting the position of a motor and self-diagnosing a defect; a second position detection sensor for detecting the position of the motor; and a control unit for receiving a position signal and a self-diagnosis signal from the first position detection sensor and receiving a position signal from the second position detection sensor, wherein the control unit determines whether the first position detection sensor is normal according to the defective (faulty) self-diagnosis signal and, if the first position detection sensor is normal, determines whether the second position detection sensor is defective by using the position signal of the first position detection sensor.

Preferably, but not necessarily, the position signal of the first position detection sensor and the position signal of the second position detection sensor may have a predetermined phase difference.

Preferably, but not necessarily, the control unit may determine whether the second position detection sensor is defective by shifting and comparing the phase of the position signal of the first position detection sensor with the phase of the position signal of the second position detection sensor.

Preferably, but not necessarily, the motor driving device may further comprise a third position detection sensor for detecting a position of the motor, wherein the position signals of the first to third position detection sensors may be out of phase by 120 degrees.

Preferably, but not necessarily, the control unit may use the position signal of the first position detection sensor to determine whether the third position detection sensor is defective, and control the motor if all of the first, second and third position detection sensors are normal.

Preferably, but not necessarily, the first position detection sensor may be an ASIL-rated Hall sensor, and the second position detection sensor may be a QM-rated Hall sensor.

In order to solve the abovementioned technical subject, there may be provided a motor driving device according to another exemplary embodiment of the first exemplary embodiment of the present invention, comprising: a first Hall sensor; a second and a third Hall sensor having different ASIL ratings from the first Hall sensor; and a control unit for receiving signals from the first to third Hall sensors and controlling the motor, wherein the control unit may receive a position signal and a self-diagnostic signal from the first Hall sensor, and receiving position signals from the second Hall sensor and the third Hall sensor to control the motor.

Preferably, but not necessarily, the control unit may determine whether the second and third hall sensors are defective by using the position signal of the first Hall sensor according to the self-diagnosis signal.

In order to solve the abovementioned technical subject, there may be provided a motor driving method according to a first exemplary embodiment of the present invention, comprising: determining whether a first position detection sensor is defective by using a self-diagnostic signal received from the first position detection sensor; shifting a phase of the position signal received from the first position detection sensor to a phase of the position signal of a second position detection sensor, if the first position detection sensor is normal; and determining whether the second position detection sensor is defective by comparing the phase of the position signal of the second position detection sensor with the phase of the position signal of the first position detection sensor.

Preferably, but not necessarily, the first position detection sensor may be an ASIL-rated Hall sensor that detects the position of the motor, and the second position detection sensor may be a QM-rated Hall sensor that detects the position of the motor.

Preferably, but not necessarily, the motor driving method may further comprise: transitioning a phase of a position signal received from the first position detection sensor to a phase of a position signal of a third position detection sensor, and determining whether the third position detection sensor is defective by comparing the position signal of the first position detection sensor with the position signal of the third position detection sensor, wherein the position signals of the first and third position detection sensors may have a phase difference of 120 degrees.

Preferably, but not necessarily, the motor driving method may further comprise: controlling the motor when all of the first to third position sensors are normal, and stopping the motor when at least one of the first to third position sensors is defective.

In order to solve the abovementioned technical subject, there may be provided a motor driving device according to a second exemplary embodiment of the present invention, comprising: a voltage detection unit connected to a plurality of Hall sensors for detecting a position of a motor and detecting a sensing voltage of the Hall sensors; and a control unit for determining whether a hall sensor is defective based on a voltage level of the sensing voltage of the voltage detection unit, wherein the control unit determines a number of the plurality of Hall sensors that are defective based on the voltage level.

Preferably, but not necessarily, the voltage detection unit may include a single resistor in connection with the plurality of Hall sensors.

Preferably, but not necessarily, the motor driving device may further comprise: a Hall sensor output input unit for receiving respective outputs of the plurality of Hall sensors; and the control unit may determine whether each Hall sensor is defective or whether a sensing circuitry of each Hall sensor is defective by using the voltage level and the output received from the plurality of Hall sensors.

Preferably, but not necessarily, the control unit may determine a defective Hall sensor by comparing the number of defective Hall sensors determined according to the voltage level and the output of each Hall sensor.

Preferably, but not necessarily, the voltage level may include a normal range, a one-failure range, a two-failure range, and a three-failure range Preferably, but not necessarily, the control unit may determine that if the voltage level is in the one-failure range, one different output of each of the Hall sensors is defective, if the voltage level is in the two-failure range, the same two outputs of each of the Hall sensors are defective, and if the voltage level is in the three-failure range, all of the Hall sensors are defective.

Preferably, but not necessarily, when all Hall sensors are normal according to the voltage level, comparative results of outputs of each Hall sensor may be compared to determine whether the sensing circuitry of each Hall sensor is defective and which Hall sensor has a defective sensing circuitry.

Preferably, but not necessarily, the control unit may include an analogue to digital converter (ADC) receiving an input of the sensing voltage detected by the voltage detection unit.

In order to solve the abovementioned technical subject, there may be provided a motor driving method according to a second exemplary embodiment of the present invention, comprising: detecting a sensing voltage of a plurality of Hall sensors detecting a position of a motor; determining if a voltage level of the sensing voltage is in a normal range; determining if a voltage level of the sensing voltage is out of a normal range, determining the number of Hall sensors that have failed based on the voltage level; and controlling the motor in a safe mode.

Preferably, but not necessarily, the method may further comprise: receiving outputs of each of the plurality of Hall sensors; and determining, using the voltage level and the outputs received from the plurality of Hall sensors, whether each Hall sensor has failed or whether a sensing circuitry of each Hall sensor has failed.

Preferably, but not necessarily, the voltage level may include a normal range, one defective range, two defective ranges, and three defective ranges.

Preferably, but not necessarily, the step of determining the defectiveness (fault) may comprise: determining that if the voltage level is in the one defective range, one different output of the respective Hall sensors is defective, if the voltage level is in the two defective ranges, the same two outputs of the respective Hall sensors are faulty, and if the voltage level is in the three defective ranges, all of the respective Hall sensors are defective.

Preferably, but not necessarily, the step of f determining the defectiveness may include determining whether the sensing circuitry of each Hall sensor is defective and the Hall sensor in which the sensing circuitry is defective using compared results of output of each Hall sensor when all the Hall sensors are normal according to the voltage level.

### Advantageous Effects

According to the embodiments of the present invention, ASIL-rated sensor signals can be used to detect faults in other QM-rated sensors and control motors. This allows for cost savings compared to using only ASIL-rated sensors.

In addition, the combination of voltage levels and sensor outputs using the integrated resistors can be used to diagnose faults in specific sensors and peripheral circuitry. Instead of using one resistor and a number of sensors, the fault diagnosis can be made using one channel ADC port of the MCU, which reduces the cost and saves two MCU ADC ports. In addition, it is possible to accurately diagnose the fault of the sensor, and it is possible to diagnose the fault of the output circuit.

### BRIEF DESCRIPTION OF DRAWINGS

FIG. 1 is a block diagram of a motor driving device according to a first embodiment of the present invention.

FIG. 2 is a block diagram of a motor driving device according to an embodiment of the present invention.

FIG. 3 is a block diagram of a motor driving device according to a comparative example of the present invention.

FIG. 4 is a block diagram of a motor driving device according to an embodiment of the present invention.

FIGS. 5 and 6 are drawings to illustrate a motor control process of a motor driving device according to an embodiment of the present invention.

FIG. 7 is a flow chart of a motor driving method according to a first embodiment of the present invention.

FIGS. 8 and 9 are flow charts of a motor driving method according to an embodiment of the present invention.

FIG. 10 is a block diagram of a motor driving device according to a second embodiment of the present invention.

FIG. 11 is a block diagram of a motor driving device according to an embodiment of the present invention.

FIGS. 12 to 16 are drawings to illustrate a Hall sensor fault determination process of a motor driving device according to an embodiment of the present invention.

FIG. 17 is a flow chart of a motor driving method according to a second embodiment of the present invention.

FIG. 18 is a flow chart of a motor driving method according to an embodiment of the present invention.

### BEST MODE

Hereinafter, exemplary embodiments of the present invention will be described in detail with reference to the accompanying drawings.

However, it should be noted that the technical ideas of the present invention should not be construed as limited to some of the explained exemplary embodiments but may be embodied in mutually different various shapes, and one or more elements may be selectively coupled or substituted among exemplary embodiments as long as within the scope of technical concept of the present invention.

Furthermore, terms (including technical and scientific terms) used in the embodiments of the present invention, unless expressly specifically defined and described, are to be interpreted in the sense in which they would be understood by a person of ordinary skill in the art to which the present invention belongs, and commonly used terms, such as dictionary-defined terms, are to be interpreted in light of their contextual meaning in the relevant art.

Furthermore, the terms used in the embodiments of the invention are intended to describe the embodiments and are not intended to limit the invention.

In this specification, the singular may include the plural unless the context otherwise requires, and references to “at least one (or more) of A and (or) B and C” may include one or more of any combination of A, B, and C that may be assembled.

In addition, the terms first, second, A, B, (a), (b), and the like may be used to describe components of embodiments of the invention. Such terms are intended only to distinguish one component from another, and are not intended to limit the nature or sequence or order of such components by such terms.

Furthermore, when a component is described as “connected,” “coupled,” or “attached” to another component, it can include cases where the component is “connected,” “coupled,” or “attached” to the other component directly, as well as cases where the component is “connected,” “coupled,” or “attached” to another component that is between the component and the other component.

Furthermore, when described as being formed or disposed “above” or “below” each component, “above” or “below” includes not only when two components are in direct contact with each other, but also when one or more other components are formed or disposed between the two components. Furthermore, when expressed as “above” or “below”, it may include the meaning of upward as well as downward with respect to a single component.

Variations according to the present embodiments may include some configurations of each embodiment together with some configurations of other embodiments, i.e., a variation may include one embodiment of the various embodiments but omit some configurations and include some configurations of the corresponding other embodiments. Alternatively, the opposite may be true. The features, structures, effects, etc. described in the embodiments are included in at least one embodiment and are not necessarily limited to any one embodiment. Furthermore, the features, structures, effects, etc. exemplified in each embodiment may be combined or modified in other embodiments by one having ordinary knowledge in the field to which the embodiments belong. Accordingly, such combinations and modifications should be construed as being within the scope of the embodiments.

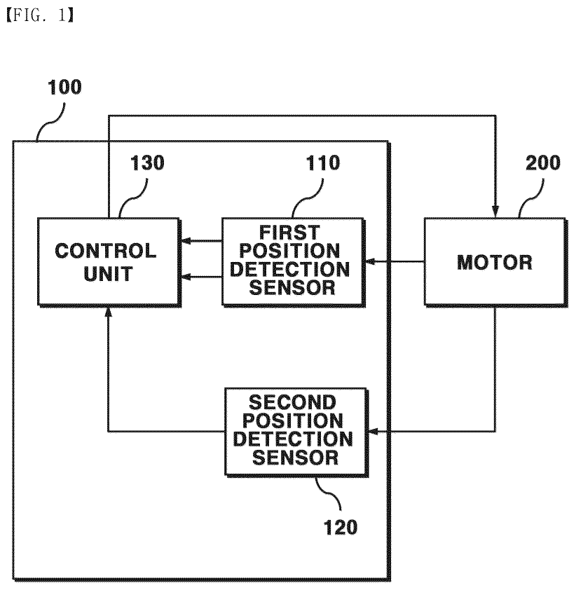

FIG. 1 is a block diagram of a motor driving device according to a first embodiment of the present invention.

The motor driving device (100) according to the first embodiment of the present invention may be formed of a first position detection sensor (110), a second position detection sensor (120), and a control unit (130), and may include a plurality of position detection sensors, connectors, inverters, position detection units, fault detection units, and the like, such as a third position detection sensor (140).

The first position detection sensor (110) may detect a position of a motor (200) and self-diagnose a fault (defectiveness).

More specifically, the first position detection sensor (110) detects the position of the motor (200) and outputs a position signal, and outputs a self-diagnosis signal through self-diagnosis. Without a separate module or device for fault diagnosis of the first position detection sensor (110), the first position detection sensor (110) can diagnose whether it is faulty by itself and output a self-diagnosis signal externally. The first position sensor 110 may be an ASIL-rated position sensor. The ASIL (Automotive Safety Integrity Level) rating is an automotive safety integrity rating, which is a risk classification rating for the functional safety of a vehicle. It means that there is no unreasonable risk of harm from the malfunctioning behavior of electrical or electronic systems and is classified based on hazard likelihood and acceptability to comply with ISO 26262. ASIL ratings are categorized into A, B, C, and D, with ASIL A being the lowest rating and ASIL D representing the highest level of vehicle risk. For example, components with the highest associated risk, such as airbags, anti-lock brakes, and power steering, may require an ASIL D rating, while the rear lights may require an ASIL A rating. ASIL ratings are categorized by measuring three variables: severity, likelihood of occurrence and controllability. The first position detection sensor may be a sensor with an AISL B rating or higher.

The second position detection sensor (120) detects the position of the motor (200).

More specifically, the second position detection sensor (120) detects the position of the motor (200) and outputs a position signal. The second position detection sensor (120) may be a position detection sensor that, unlike the first position detection sensor (110), does not self-diagnose for faults. The second position detection sensor (120) may detect the position of the motor (200) at a different position or in a different direction than the first position detection sensor (110). The second position detection sensor (120) may be a QM-rated position detection sensor. A Quality Management (QM) rating is a rating that does not require additional risk mitigation measures beyond an industry acceptable quality system, such as satisfactory quality for normal operation, but is not configured for additional measures for functional safety, such as self-diagnostics. In order to determine whether the second position detection sensor (120) with a QM rating has failed, an additional device is required.

Alternatively, the first position detection sensor (110) and the second position detection sensor (120) may be position detection sensors with ASIL ratings, but may be position detection sensors with different ASIL ratings. In this case, the first position detection sensor (110) may have a higher ASIL rating than the second position detection sensor (120). For example, the first position detection sensor (110) may be a position detection sensor with an ASIL B rating and the second position detection sensor (120) may be a position detection sensor with an ASIL A rating.

The control unit (130) receives a position signal and a self-diagnostic signal from the first position detection sensor (110) and a position signal from the second position detection sensor (120).

More specifically, the control unit (130) receives the position signal and the self-diagnosis signal from the first position detection sensor (110), determines whether the first position detection sensor is normal according to the self-diagnosis signal, and, if the first position detection sensor is normal, determines whether the second position detection sensor is malfunctioning using the position signal of the first position detection sensor (110).

The position signal and the self-diagnosis signal of the first position detection sensor (110) may be inputted to the control unit (130) as a single signal. In the signal, the position signal may have a pulse and the self-diagnosis signal may have a tick signal. The control unit (130) may classify the position signal and the self-signal from the single signal. If the self-signal is implemented as a tick signal, if a tick signal is inputted, it can be judged as normal, and if a tick signal is not inputted or is not inputted for a certain period of time, it can be judged as a malfunction (as defective). Various other types of signals can be used as self-diagnostic signals. It is also obvious that the position signal and the self-diagnostic signal may be inputted to the control unit (130) as separate signals.

The control unit (130) controls the motor (200) by generating a control signal to control the motor (200) using the position signal of the first position detection sensor and the position signal of the second position detection sensor. The current position of the motor (200) and the change in position may be used to control the displacement or speed of the motor (200). The motor (200) may include an actuator to drive the motor (200), and the control unit (130) may control the actuator to drive the motor (200).

The control unit (130) may ensure reliability of motor control by controlling the motor (200) using each position signal to control the motor (200) when the position signal of the first position detection sensor and the position signal of the second position detection sensor are normal. If the position signals are used to control the motor (200) without verification of the position signals, it may be difficult to ensure reliability of the motor (200). In particular, if the motor (200) requires high reliability, verification of the position signal may be essential.

A predetermined ASIL rating may be required for the position detection sensors, including the first position detection sensor (110) and the second position detection sensor (120). A position detection sensor capable of self-fault diagnosis may be required, for example, an ASIL B rating or higher. In this case, if all the position detection sensors are applied as position detection sensors with an ASIL rating, it is costly and additional connection lines for receiving each self-fault diagnosis signal are required.

To solve this problem, the control unit (130) first determines whether the first position detection sensor (110) is normal according to a self-diagnosis signal received from the first position detection sensor (110). For example, if the self-diagnostic signal is a tick signal, it may be determined whether the self-diagnostic signal is faulty or normal based on the input of the self-diagnostic signal. If the first position detection sensor (110) is normal according to the self-diagnostic signal, the control unit (130) may trust the position signal of the first position detection sensor 110 and use it to control the motor (200). Based on the reliability of the position signal of the first position detection sensor (110), a failure of the position signal of the second position detection sensor (120) is determined. Based on the position signal of the first position detection sensor (110), a failure of the second position detection sensor (120) can be determined in comparison to the second position detection sensor (120). The position signal of the first position detection sensor (110) and the position signal of the second position detection sensor (120) may be position signals having a predetermined phase difference. The first position detection sensor (110) and the second position detection sensor (120) may be Hall sensors that are spaced apart from each other at a certain spacing angle to detect the position of the rotating motor (200). The first position detection sensor (110) and the second position detection sensor (120) may be spaced apart at an angle of 120 degrees.

The control unit (130) may determine whether the second position detection sensor has failed by comparing the phase of the position signal of the first position detection sensor (110), which is determined to be normal, with the phase of the position signal of the second position detection sensor (120). Since the first position detection sensor (110) and the second position detection sensor (120) detect the position of the same motor (200), the signals may have different phases but may have the same magnitude or magnitude features. Using this point, the phase of the position signal of the first position detection sensor (110), which is determined to be normal, can be compared with the phase of the position signal of the second position detection sensor (120) to determine whether the second position detection sensor has failed. If the position signal of the first position detection sensor (110) and the position signal of the second position detection sensor (120) have a 120 degree phase difference, the position signal of the first position detection sensor (110) is phase-shifted by 120 degrees and compared to the position signal of the second position detection sensor (120), and if the difference between the position signal of the first position detection sensor (110) and the position signal of the second position detection sensor (120) is below a threshold value, that is, within a normal range, the second position detection sensor (120) can be determined to be normal. The normal range may be set according to the user's or Hall sensor's sensitivity, the sensitivity of the motor control unit or motor, or the degree of accuracy required.

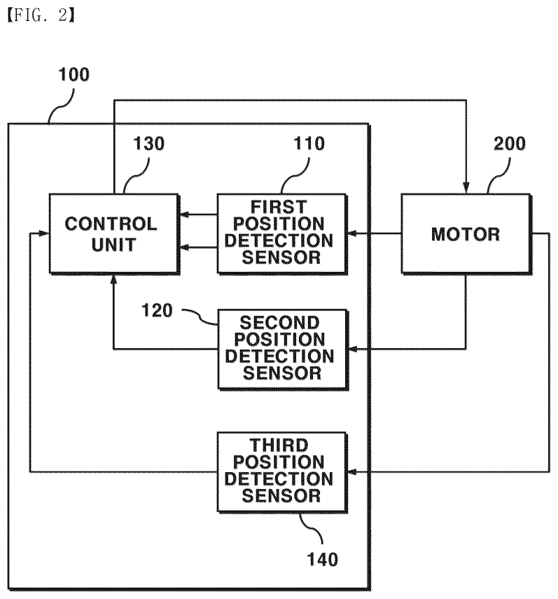

Along with the first position detection sensor (110) and the second position detection sensor (120), the motor (200) may include a third position detection sensor (140) that detects the position of the motor (200). In this case, the position signals of the first to third position detection sensors may be out of phase by 120 degrees. As shown in FIG. 2, the first to third position detection sensors (110, 120, 140) may each measure the position of the motor (200) and output a position signal, but only the first position detection sensor (110) may output a self-diagnostic signal. Alternatively, two of the three position detection sensors may output a self-diagnostic signal. The motor (200) may be a rotary motor, and the first to third position sensors (110, 120, 140) may be out of phase by 120 degrees. The third position detection sensor (140) may be a Hall sensor having a QM rating as the position detection sensor corresponding to the second position detection sensor (120). The detailed description of the third position detection sensor (140) corresponds to the detailed description of the second position detection sensor (120), and duplicate descriptions will be omitted.

In response to the process of determining whether the first position detection sensor (110) is malfunctioning (defective) and determining whether the second position detection sensor (120) is malfunctioning using the position signal of the first position detection sensor (110), the position signal of the first position detection sensor 110 can be used to determine whether the third position detection sensor (140) is malfunctioning. In other words, the phase of the position signal of the first position detection sensor (110) may be compared with the phase of the position signal of the third position detection sensor (140) to determine whether the third position detection sensor has failed. Alternatively, the phase of the position signal of the second position detection sensor (120), which is determined to be normal by comparison with the position signal of the first position detection sensor (110), may be transiently compared with the phase of the position signal of the third position detection sensor (140) to determine whether the third position detection sensor has failed.

The control unit (130) can control the motor (200) when the first to third position detection sensors (110, 120, 140) are all normal. If the first to third position detection sensors (110, 120, 140) are all normal, the respective position signals can be trusted and the motor (200) can be controlled using the respective position signals. If at least one of the first to third position detection sensors (110, 120, 140) is faulty, the motor (200) can be safely operated or stopped.

As described above, one position detection sensor capable of self-diagnosis can be used to determine the failure of other types of position detection sensors that do not perform self-diagnosis. In this way, by using a Hall sensor with one ASIL rating, functional safety can be satisfied even if a Hall sensor with a QM rating other than ASIL is used. In addition, the number of connecting wires for receiving self-diagnostic signals can be reduced. This enables efficient utilization of space and reduces costs.

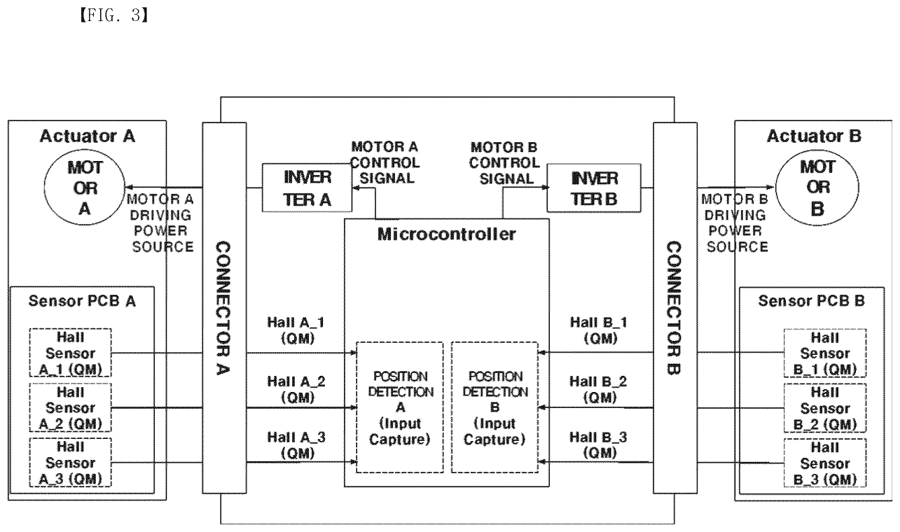

FIG. 3 is a comparative example of the present invention, which may be a motor control unit controlling two motors. Each motor comprises an actuator, each actuator comprises a three-phase BLDC motor, uses three Hall sensors (QM) for rotor position detection, and receives the position signals of the Hall sensors through a connector to detect the respective phases, i.e., positions. A motor control signal is applied to the inverter to control the motor using the detected position, and the motor control signal is provided as the motor driving power through the operation of the inverter. Here, the inverter may include one or more upstream switches and one or more downstream switches that are complementary to each other. The control unit may be a microcontroller and may drive the motor using motor control signals.

If there are no functional safety requirements, it is acceptable to use a QM-rated Hall sensor to control the motor, but if there are ASIL-rated requirements, safety goals must be met. There are limitations to using QM-rated Hall sensors for fault detection. Therefore, an ASIL-rated Hall sensor must be used, but ASIL-rated Hall sensors are more expensive than QM products and require additional connecting wires.

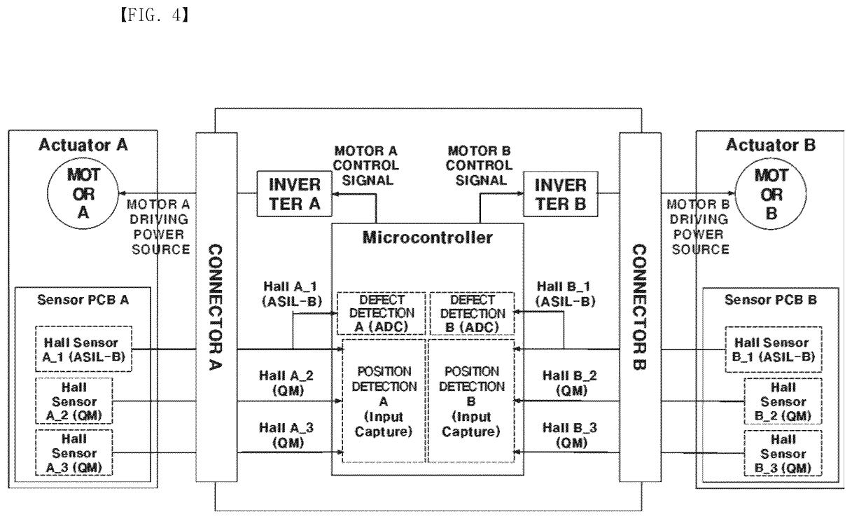

FIG. 4 is a motor control device according to an embodiment of the present invention corresponding to the comparative example of the present invention of FIG. 3.

In order to satisfy functional safety along with motor position detection, each actuator may utilize two Hall sensors (QM) for detecting motor position and one Hall sensor (ASIL) for detecting motor position and fault. The signals from the Hall sensors (ASIL) are inputted to the connector via a single connection wire and are divided into a self-diagnostic signal and a position signal. The position signal for motor operation is inputted to the position detection unit (Input Capture) with three connecting wires, and the self-diagnosis signal is inputted to the fault detection unit (ADC) with one connecting wire. The self-diagnostic signal and position signal can be used to determine whether the three Hall sensors are faulty. In other words, functional safety for all Hall sensors can be satisfied by adding only one connection line for the self-diagnostic signal. In other words, functional safety can be satisfied with only one interface to the ADC instead of three.

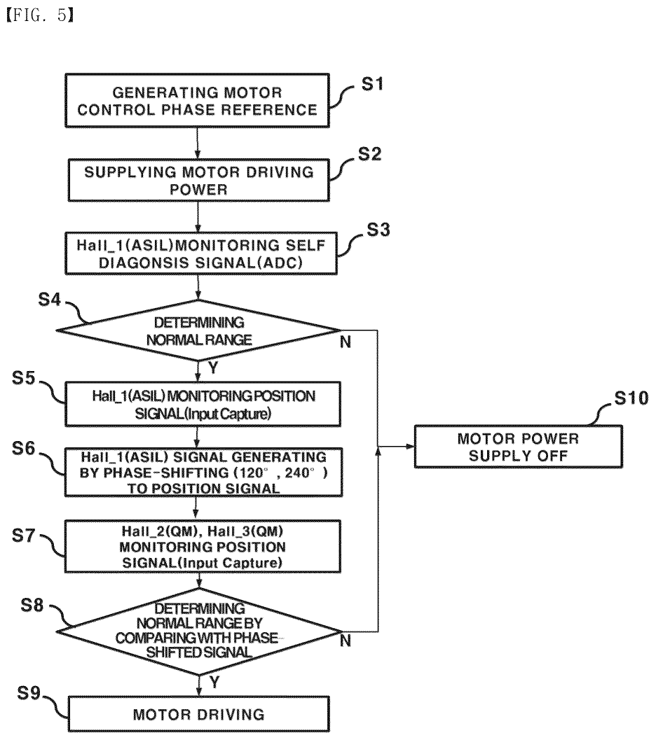

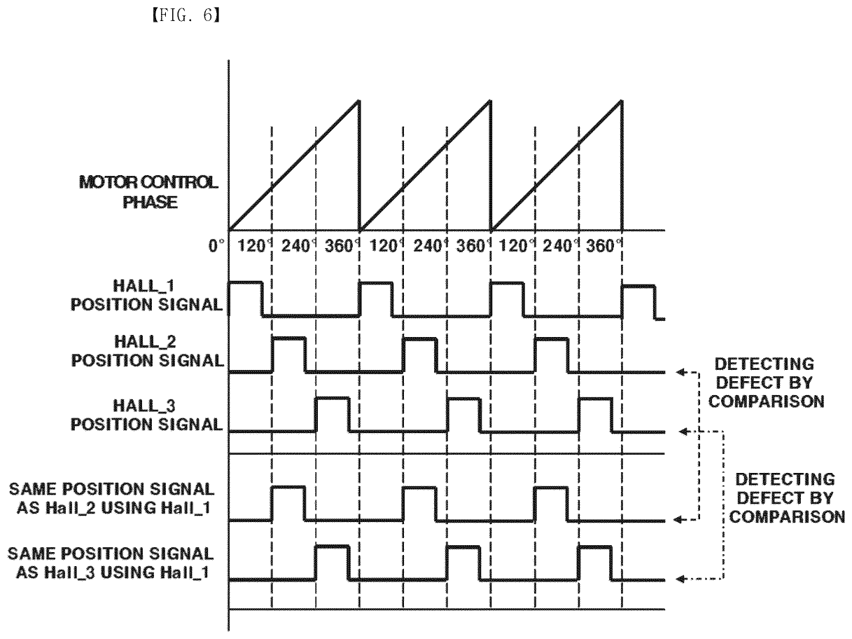

FIG. 5 shows a process for determining whether a Hall sensor is faulty, first generating a motor control phase reference S1 and supplying power to drive the motor (S2). The motor control phase reference can be generated as shown in FIG. 6. The first Hall sensor (ASIL) self-diagnosis signal is monitored (S3) through the fault detection section (ADC) to determine whether the self-diagnosis signal is in the normal range (S4). If the self-diagnosis signal meets the normal range, the motor position signal of the first Hall sensor (ASIL) is monitored (S5) through the position detection unit (input capture). The position signals of the first to third Hall sensors may be as shown in FIG. 6, and a comparison signal is generated (S6) by phase-shifting the position signal of the first Hall sensor (ASIL), and the position signals of the second Hall sensor (QM) and the third Hall sensor (QM) are monitored (S7) through the position detection unit (input capture) to determine whether they are in the normal range (S8) by comparing them with the phase-shifted signal. If it is within the normal range, the position signals of the first to third Hall sensors are normal, and the motor is driven (S9) based on this. If the position signal of at least one Hall sensor is out of the normal range as a result of S4 or S8, the motor power supply is cut off (S10).

A motor control device according to another embodiment of the present invention includes a first Hall sensor, a second Hall sensor and a third Hall sensor having different ASIL ratings from the first Hall sensor, and a control unit for receiving signals from the first to third Hall sensors and controlling the motor, the control unit receiving position signals and self-diagnostic signals from the first Hall sensor, and receiving position signals from the second Hall sensor and the third Hall sensor to control the motor. A detailed description of each configuration of the motor control unit according to another embodiment of the present invention corresponds to the detailed description of the motor control unit in FIGS. 1 to 6, and hereinafter redundant descriptions will be omitted.

The control unit may determine whether the second and third Hall sensors are malfunctioning by using the position signal of the first Hall sensor according to the self-diagnosis signal. When the first Hall sensor is normal, the position signal of the first Hall sensor is phase-shifted and compared with the position signals of the second and third Hall sensors to determine whether they are within the normal range to determine whether the second and third Hall sensors are faulty. If both are normal, the respective position signals can be used to control the motor, and if at least one is faulty, the motor can be stopped.

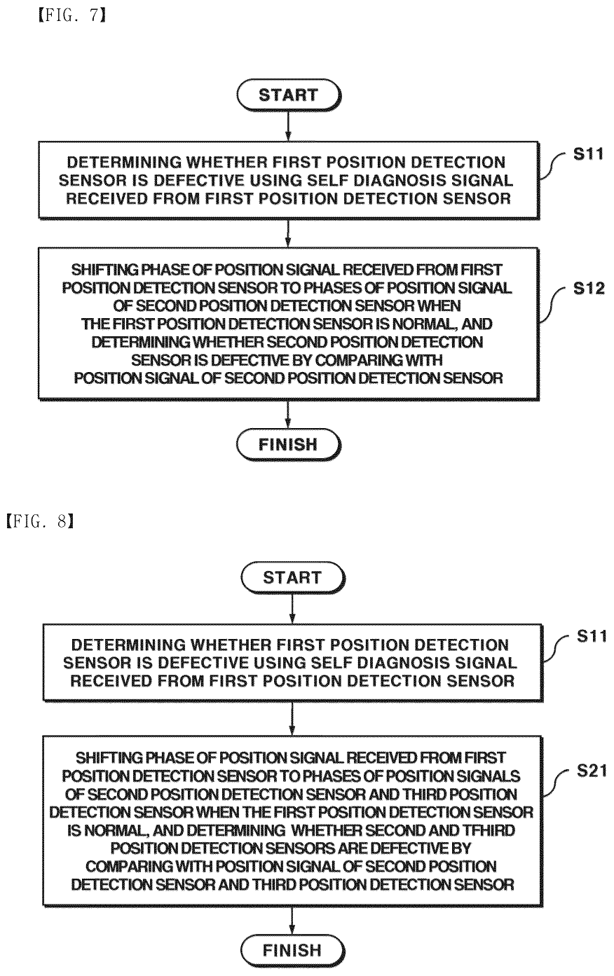

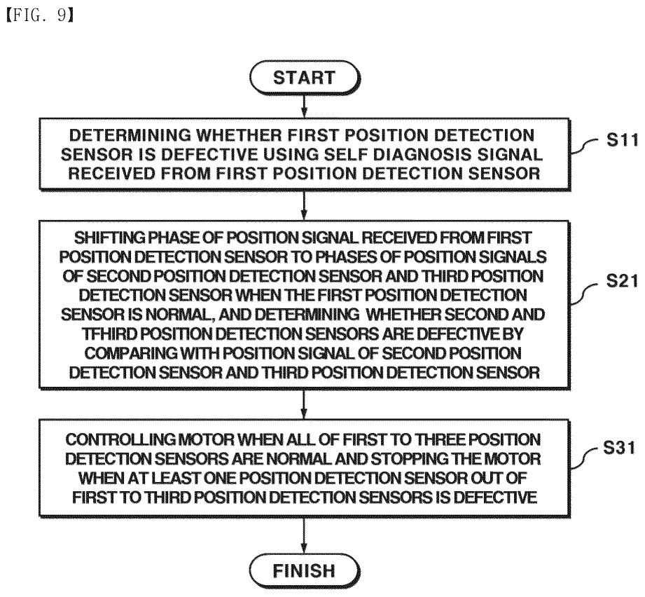

FIG. 7 is a flow chart of a motor driving method according to a first embodiment of the present invention, and FIGS. 8 and 9 are flow charts of a motor driving method according to an embodiment of the present invention. The detailed description of each step in FIGS. 7 to 9 corresponds to the detailed description of the motor driving device in FIGS. 1 to 6, and the redundant description will be omitted hereinafter.

In controlling the motor, in step S11, a self-diagnostic signal received from the first position detection sensor is used to determine whether the first position detection sensor is malfunctioning, and if the first position detection sensor is normal as a result of the determination in step S11, the phase of the position signal received from the first position detection sensor is shifted to a phase of the position signal of the second position detection sensor in step S12, and the phase of the position signal of the second position detection sensor is compared with the phase of the position signal of the second position detection sensor to determine whether the second position detection sensor is malfunctioning.

The motor driving device may comprise a third position detection sensor in addition to a first position detection sensor and a second position detection sensor. The position signals of the first and third position detection sensors may be out of phase by 120 degrees. If, as a result of the determination in step S11, the first position detection sensor is normal, in step S21, the phase of the position signal received from the first position detection sensor is shifted (switched) to the phase of the position signals of the second position detection sensor and the third position detection sensor, and a failure of the second position detection sensor and the third position detection sensor is determined by comparing the position signal of the second position detection sensor and the position signal of the third position detection sensor.

Based on the result of determining whether the first to third position detection sensors are faulty (defective), the motor may be controlled in step S31 if the first to third position detection sensors are all normal, and the motor may be stopped if at least one of the first to third position detection sensors is faulty.

Here, the first position detection sensor may be a Hall sensor having an ASIL class to detect the position of the motor, and the second position detection sensor or the third position detection sensor may be a QM class Hall sensor to detect the position of the motor.

As described above, the self-diagnostic signal of the first position detection sensor is sufficient to determine whether the first to third position detection sensors have failed. In this way, the ASIL-rated sensor signal can be used to detect the failure of the other QM-rated sensors and control the motor. This enables cost savings compared to using only ASIL-rated sensors.

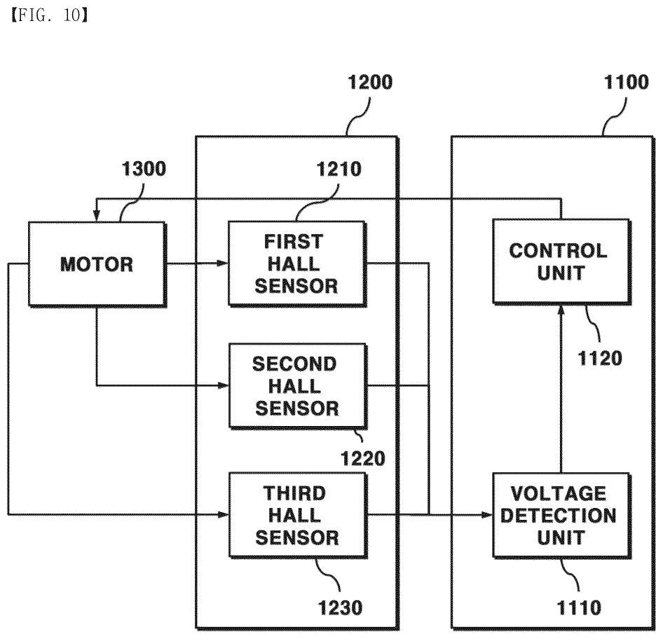

As described above, the motor driving device and the motor driving method according to the first exemplary embodiment of the present invention have been described with reference to FIGS. 1 to 9. Hereinafter, a motor driving device and a motor driving method according to a second exemplary embodiment of the present invention will be described with reference to FIGS. 10 to 18. The detailed description of the motor driving device and motor driving method according to the second embodiment of the present invention is based on the detailed description of each first embodiment, and the names, terms, and features may be the same or different from those of the motor driving device and motor driving method according to the first embodiment of the present invention.

FIG. 10 is a block diagram of a motor driving device according to a second embodiment of the present invention.

A motor driving device (1100) according to a second embodiment of the present invention may comprise: a voltage detection unit (1110); and a control unit (1120), and may further comprise a Hall sensor output input unit (1130), an input port, an analogue-to-digital converter (ADC), and the like.

The voltage detection unit (1110) is coupled to a plurality of Hall sensors (1210, 1220, 1230) that detect the position of a motor (1300) to detect the sensing voltage of the Hall sensors (1210, 1220, 1230).

More specifically, the voltage detection unit (1110) detects the sensing voltage that is applied to the Hall sensors (1210, 1220, 1230) and output from the Hall sensors 1210, 1220, 1230 to drive the Hall sensors 1210, 1220, 1230 to detect the position of the motor (1300). The voltage detection unit (1110) is connected to each of the hall sensors 1210, 1220, 1230 to detect the sum of the sensing voltages. The Hall sensors (1210, 1220, 1230) may include Hall sensor elements of a latch type of Hall effect IC. They may be mounted on a Hall sensor substrate (1200) to detect the position of the motor (1300). The Hall sensor substrate (1200) on which the Hall sensors (1210, 1220, 1230) are mounted may be a printed circuit board (PCB). The motor (1300) may be a BLDC three-phase motor, and the Hall sensor may include three Hall sensors, each capable of detecting the position of the motor (1300) with a phase difference of 120 degrees. It may also include two or four or more Hall sensors, depending on need or design.

The voltage detection unit (1110) may include a single resistor in connection with the plurality of Hall sensors. The voltage detection unit (1110) may be implemented as a single resistor to detect a voltage. Here, the resistor may be a sensing resistor, such as a shunt resistor. Depending on the current outputted from the output unit of each Hall sensor (1210, 1220, 1230), the resistor can be used to detect the sensing voltage. By using a single resistor to detect the sensing voltage of a plurality of Hall sensors (1210, 1220, 1230), the sensing voltage of all Hall sensors (1210, 1220, 1230) may be detected rather than the sensing voltage of each Hall sensor (1210, 1220, 1230). By detecting the sensing voltage of each Hall sensor (1210, 1220, 1230) with a single resistor instead of detecting the sensing voltage of each resistor, the number of resistors can be reduced, and the number of signal lines or input ports that carry the sensing voltage can be reduced.

The control unit (1120) determines whether the Hall sensor has failed based on the voltage level of the sensing voltage of the voltage detection unit (1110).

More specifically, the control unit (1120) receives the sensing voltage detected by the voltage detection unit (1110) and determines whether the Hall sensor has failed based on the voltage level of the sensing voltage.

The control section (1120) may include an analogue to digital converter (ADC) that receives the sensing voltage detected by the voltage detection unit (1110). The control unit (1120) may be an MCU that drives the motor and may be connected to each of the Hall sensors (1210, 1220, 1230) via a respective connecting line or a connector via a connecting line that integrates the Hall sensors (1210, 1220, 1230), and the voltage detection unit (1110) may include an input port that functions as an analogue to digital converter.

The control unit (1120) may determine whether the Hall sensors (1210, 1220, 1230) have failed based on the voltage level and, if so, determine how many of the plurality of Hall sensors (1210, 1220, 1230) have failed.

The control unit (1120) may distinguish between voltage levels based on the magnitude of the sensing voltage. The control unit (1120) may determine that the Hall sensors (1210, 1220, 1230) are normal if the voltage level of the sensing voltage corresponds to a voltage level that is detected in normal operation of all of the plurality of Hall sensors (1210, 1220, 1230), and may determine that the Hall sensors (1210, 1220, 1230) are not normal if the voltage level is outside the normal range. Not only the normal range of voltage level, but also the fault range can be set separately.

The voltage levels may include a normal range, a one-failure range, a two-failure range, and a three-failure range, i.e., a voltage range outside of the normal range, a voltage range in which one of the Hall sensors fails, a voltage range in which two of the Hall sensors fail, and a voltage range in which three of the Hall sensors fail, to determine whether the voltage level is normal, whether it is a failure, and, if so, how many of the Hall sensors have failed. For example, the voltage level in the normal range may be 4.23 V, the voltage level in the one-failure range may be 2.96 V, the voltage level in the two-failure range may be 1.69 V, and the voltage level in the three-failure range may be 0.42 V. The voltage level can also be set in sections. The voltage level may be set according to the detection of the actual output sensing voltage or may be set by the user.

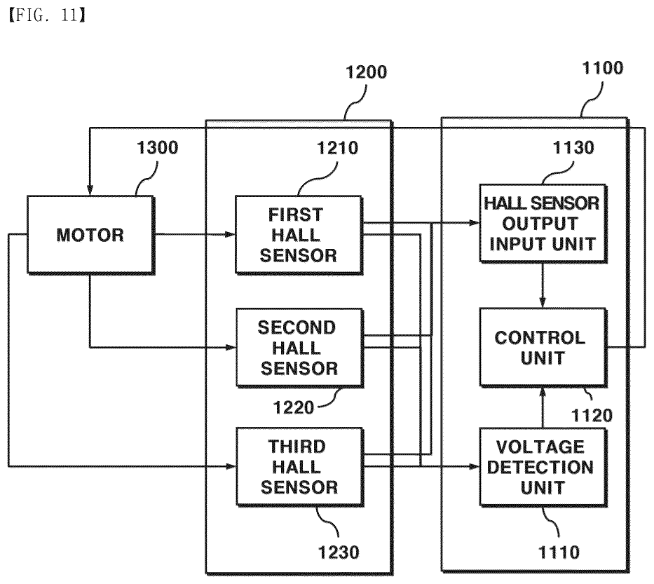

Hall sensor output input unit (1130) may receive respective outputs of the plurality of Hall sensors (1210, 1220, 1230). As shown in FIG. 11, the voltage detection unit (1110) may detect a sensing voltage of the Hall sensors (1210, 1220, 1230), and the Hall sensor output input unit may receive a Hall sensor output that outputs a signal that the Hall sensors (1210, 1220, 1230) have detected a position of the motor (1300). In other words, the Hall sensor output may include a position signal of the motor (1300). The Hall sensor output input unit (1130) may be an input port associated with each Hall sensor to receive position signals. Here, the input port may be a GPIO input port with a filter and input capture function. The output pattern of the Hall sensor is inputted to the GPIO port and converted into a position signal pulse through the input capture function, which can be used to control the motor.

As described earlier, the voltage level can be inputted to the ADC input port and the Hall sensor output can be inputted to the GPIO input port to meet ASIL A or higher. The ASIL (Automotive Safety Integrity Level) rating is an automotive safety integrity rating, which is a risk classification rating for the functional safety of the vehicle. It means that there is no unreasonable risk of harm from the malfunctioning behavior of electrical or electronic systems, and is classified based on risk likelihood and acceptability to comply with ISO 26262. ASIL ratings are categorized into A, B, C, and D, with ASIL A being the lowest rating and ASIL D representing the highest level of vehicle risk. For example, components with the highest associated risk, such as airbags, anti-lock brakes, and power steering, require an ASIL D rating, while rear lights may require an ASIL A rating. ASIL ratings are categorized by measuring three variables: severity, likelihood of occurrence, and controllability.

The control unit (1120) may use the voltage levels and the outputs received from the plurality of Hall sensors to determine whether each Hall sensor has failed or whether the sensing circuitry of each Hall sensor has failed. When driving a motor (1300), the outputs of the normally operating Hall sensors (1210, 1220, 1230) are identical Hall sensor outputs with only a phase difference therebetween. If the Hall sensor outputs are different, it may indicate that one of the sensors outputting different Hall sensor outputs has failed. However, if the Hall sensor outputs are different, it is not possible to determine which Hall sensor has failed. In view of this, it is possible to determine which of the Hall sensors (1210, 1220, 1230) has failed by comparing the Hall sensor outputs with the previously detected and determined voltage level.

The control unit (1120) may determine the faulty Hall sensor by comparing the number of faulty Hall sensors determined by the voltage level and the output of each Hall sensor. The voltage level may include a normal range, a one-failure range, a two-failure range, and a three-failure range, and since the number of faulty Hall sensors is known according to the voltage level, the number of Hall sensors with different outputs may be used to determine which Hall sensors are normal and which Hall sensors are faulty.

The control unit (1120) may determine that if the voltage level is in the one-failure range, one different output of each of the Hall sensor outputs is faulty, if the voltage level is in the two-failure range, the same two outputs of each of the Hall sensor outputs are faulty, and if the voltage level is in the three-failure range, all of the Hall sensors are faulty.

If the voltage level is in the one-failure range, one Hall sensor is in a fault state, and the output of one Hall sensor among the three Hall sensor outputs is different, it can be determined that a different Hall sensor is in a fault state. If the voltage level is in the two-failure ranges, two Hall sensors are faulty, and if two of the three Hall sensor outputs are the same and one Hall sensor output is different, it can be determined that the same two Hall sensors are faulty. If the voltage level is in the three-failure range, all three Hall sensors are failed, and it can be determined that all Hall sensors are failed.

If the number of failures of the Hall sensors according to the voltage level and the results of comparing the outputs of each Hall sensor do not match each other, the control unit (1120) may determine that a failure of the sensing circuitry has occurred.

The control unit (1120) may determine whether the sensing circuitry of each Hall sensor has failed and which Hall sensor has failed using the result of comparing the output of each Hall sensor when all Hall sensors are normal according to the voltage level above. If the outputs of the Hall sensors are different even though the voltage level is within a normal range, it can be determined that there is an abnormality in the sensing circuitry that outputs the position signal of the motor (1300) detected by the Hall sensors. For example, if the voltage level is in the normal range and the output of one Hall sensor is different, it may be determined that the sensing circuitry of that Hall sensor is malfunctioning.

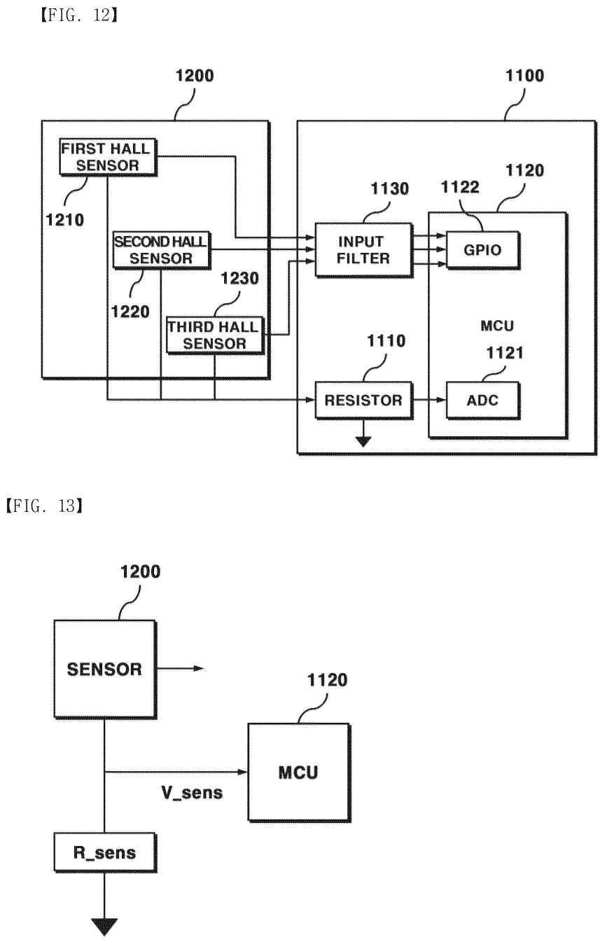

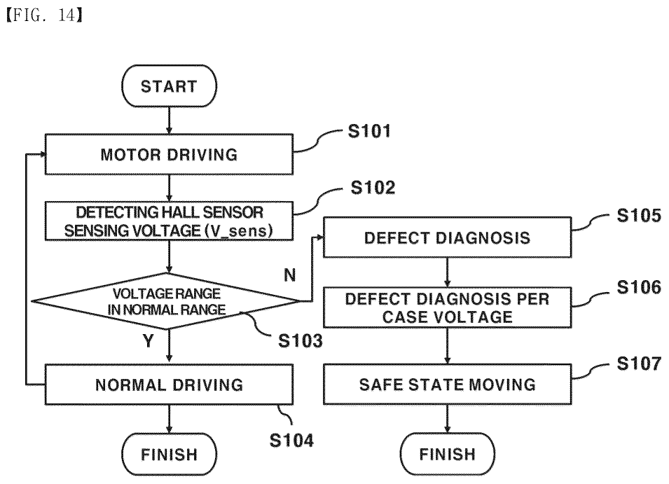

A motor driving device according to an embodiment of the present invention may be implemented as shown in FIG. 12. Three Hall sensors (1210, 1220, 1230) are disposed on a Hall sensor substrate (1200) to detect the position of the motor. The position signals detected by the Hall sensors (1210, 1220, 1230) may be inputted to the GPIO input port (1122) of an MCU (1120), the control unit, through an input filter (1130) as the Hall sensor output. In order to detect the sensing voltages of the Hall sensors (1210, 1220, 1230) separately from the Hall sensor output, each Hall sensor (1210, 1220, 1230) may be connected with one resistor (1110) and the sensing voltage may be inputted to the ADC input port (1121) of the MCU (1120). In this case, the sensing voltage may be a current flowing through the Hall sensor connected to the resistor (R_sens), such that the sensing voltage (V_sens) is inputted to the ADC input port (1121) of the MCU (1120), as shown in FIG. 13.

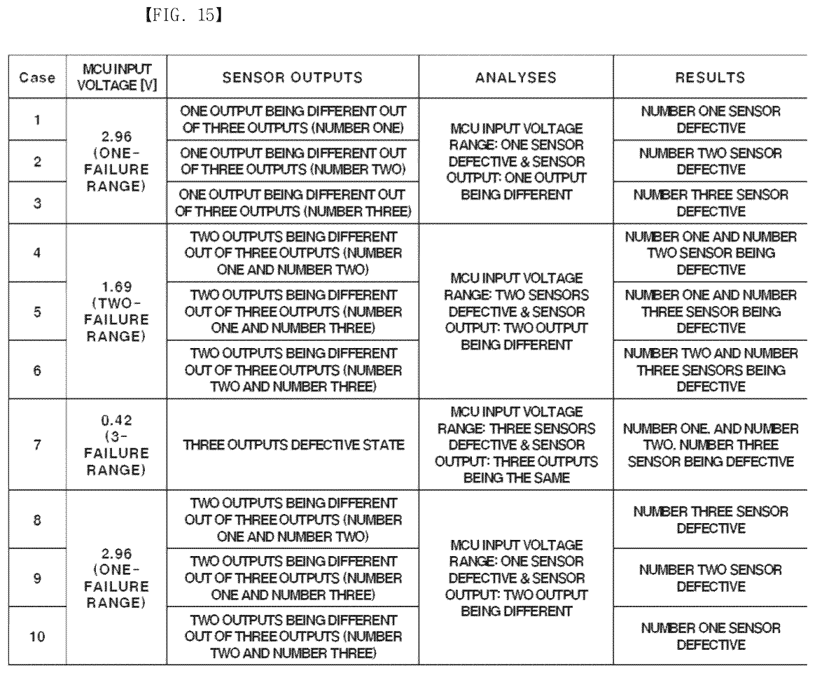

The process by which the control unit (1120) determines whether the Hall sensor has failed may be performed as shown in FIG. 14. When the motor is operated (S1), the Hall sensor detects the sensing voltage (S2), which is the voltage when the Hall sensor senses the motor, determines whether the voltage level of the sensing voltage is within the normal range (S3), and if it is within the normal range, the motor is operated normally (S4). If the voltage level of the sensing voltage is outside the normal range, a Hall sensor failure is diagnosed (S5), and the failure is diagnosed by case voltage by comparing the voltage level and the Hall sensor output (S6) to diagnose which Hall sensor or sensing circuitry has failed, and the motor is controlled (S7) in a safe state after the failure (fault) is diagnosed.

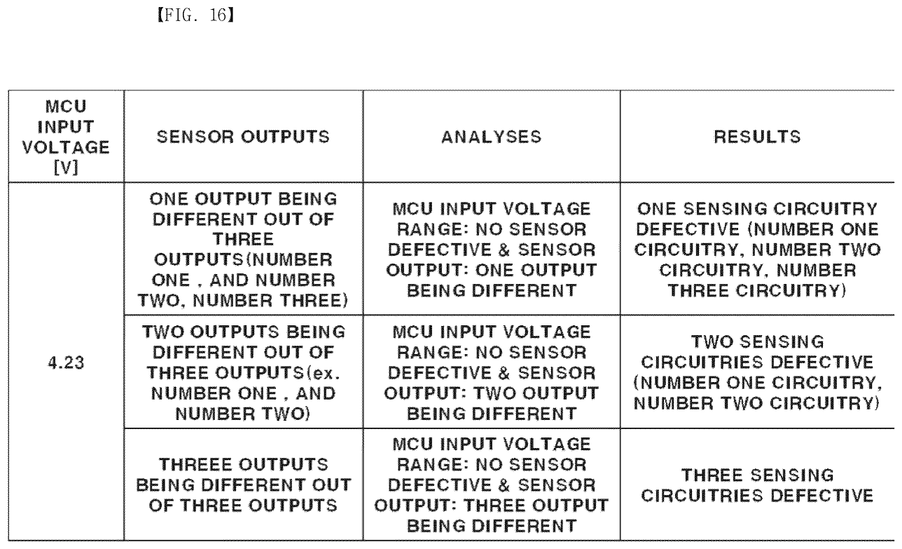

The fault (failure, defect) diagnosis according to the voltage level may be determined as shown in FIG. 15 or FIG. 16. FIGS. 15 and 16 show a case-by-case classification of the fault situation, which is stored in the storage in the form of a data Table, and the control unit (1120) can use it to perform the fault diagnosis.

If the voltage level is in the normal range and the Hall sensor outputs are all normal, the condition is considered normal. If the voltage level is in one-failure range, if there is one output of the three Hall sensor outputs that is different, it can be determined that the corresponding Hall sensor has failed. (cases 1,2,3). If the voltage level is in the two-failure range, if there are 2 different outputs among the three Hall sensor outputs, it can be judged that the two Hall sensors have failed. (cases 4,5,6) If the voltage level is in the three-failure range, it can be judged that all the Hall sensors have failed. (case 7). If the voltage level is in one-failure range, if there are two different outputs of three Hall sensors, it can be judged that one Hall sensor other than the corresponding Hall sensor has failed. (cases 8,9,10).

If the voltage level is in the normal range, but the Hall sensor outputs include different Hall sensor outputs, a malfunction of the sensing circuitry can be determined as shown in FIG. 16. If the voltage level is in the normal range, but the output of one of the three Hall sensor outputs is different, the sensing circuitry of that Hall sensor is judged to be faulty; if the output of two of the three Hall sensor outputs is different, the sensing circuitry of those two Hall sensors is judged to be faulty; and if the output of three of the three Hall sensor outputs is different, the sensing circuitry of all the Hall sensors is judged to be faulty.

As described above, it is possible to implement functional safety by using one resistor to diagnose whether the sensor and sensing circuitry are faulty through the combination of voltage level and sensor output. Since the fault diagnosis can be made using one channel ADC port of the MCU, which is a motor driving device, rather than one resistor and a number of sensors, the cost can be reduced, and two ADC ports can be saved.

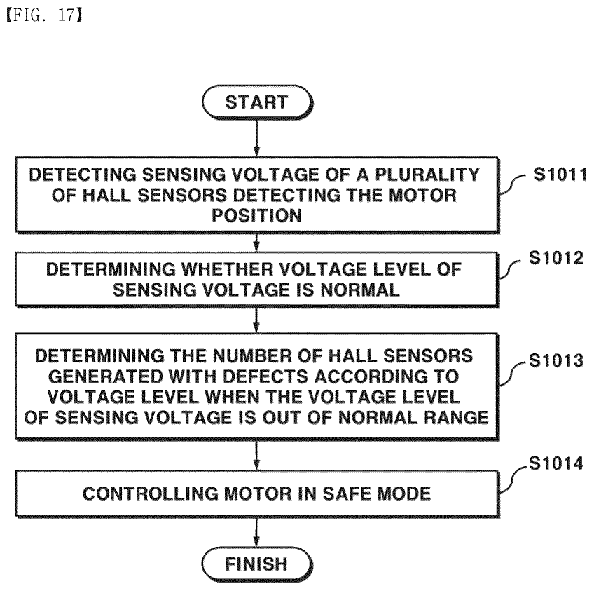

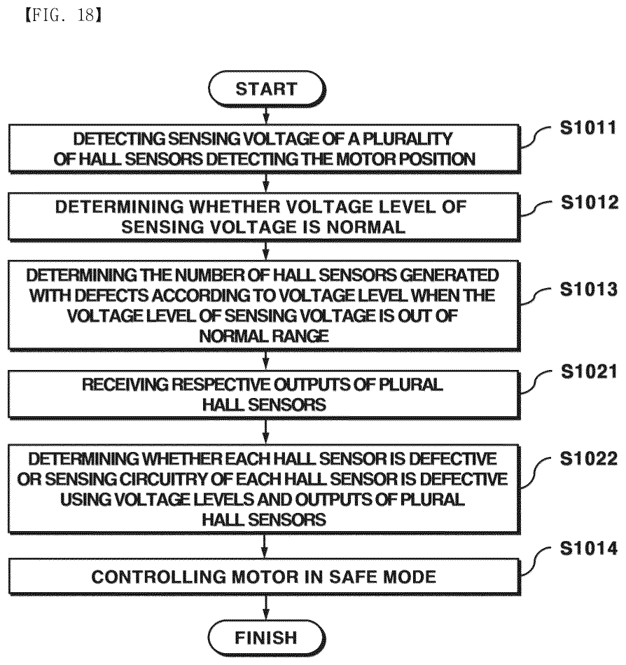

FIG. 17 is a flow chart of a motor driving method according to the second exemplary embodiment of the present invention, and FIG. 18 is a flow chart of a motor driving method according to an embodiment of the present invention. The detailed description of each step in FIGS. 17 and 18 corresponds to the detailed description of the motor driving device in FIGS. 10 to 16, and the redundant description will be omitted hereinafter.

In order to determine whether a Hall sensor has failed, in step S1011, the sensing voltage of a plurality of Hall sensors detecting the position of the motor is detected, in step S1012, the voltage level of the sensing voltage is determined to be within a normal range, and if the voltage level of the sensing voltage is outside the normal range as a result of the determination in step S1012, in step S1013, the number of Hall sensors that have failed according to the voltage level is determined, and in step S1014, the motor is controlled in a safe mode.

If, as a result of the determination in step S1012, the voltage level of the sensing voltage is outside the normal range, in order to determine which of the Hall sensors is malfunctioning, in step S1021, the respective outputs of the plurality of Hall sensors are received, and in step S1022, the voltage level and the outputs received from the plurality of Hall sensors are used to determine whether each Hall sensor is malfunctioning or whether the sensing circuitry of each Hall sensor is malfunctioning.

The voltage level may include a normal range, a one-failure range, a two-failure range, and a three-failure range, and if the voltage level is in the one-failure range, it may be determined that a different one of the outputs of each of the Hall sensors is faulty, if the voltage level is in the two-failure range, it may be determined that the same two of the outputs of each of the Hall sensors are faulty, and if the voltage level is in the three fault range, it may be determined that all of the Hall sensors are faulty.

Furthermore, it is possible to determine whether the sensing circuitry of the Hall sensor is malfunctioning. When all the Hall sensors are normal according to the voltage level, the result of comparing the output of each Hall sensor can be used to determine whether the sensing circuitry of each Hall sensor is malfunctioning and the Hall sensor whose sensing circuitry is malfunctioning.

Using a single resistor, it is possible to diagnose whether the sensor and sensing circuitry are malfunctioning by combining the voltage level and sensor output to implement functional safety. The fault diagnosis can be performed using one channel ADC port of the MCU, which is a motor driving device, rather than one resistor and a number of sensors, thus reducing the cost and saving two ADC ports.

A variant according to the present embodiment may include some configurations of the first exemplary embodiment together with some configurations of the second exemplary embodiment, i.e., the variant may include the first embodiment but omit some configurations of the first embodiment and include some configurations of the corresponding second embodiment. Alternatively, a variant may include the second embodiment but omit some configurations of the second embodiment and include some configurations of the corresponding first embodiment.

The features, structures, effects, etc. described above in the embodiments are included in at least one embodiment and are not necessarily limited to one embodiment. Furthermore, the features, structures, effects, etc. exemplified in each embodiment may be combined or modified in other embodiments by one having ordinary knowledge in the field to which the embodiments belong. Accordingly, such combinations and modifications should be construed as being within the scope of the embodiments.

Embodiments of the present invention can be implemented as computer-readable code on a computer-readable recording medium. A computer-readable recording medium includes any kind of recording device on which data that can be read by a computer system is stored.

Examples of computer-readable recording media include ROM, RAM, CD-ROM, magnetic tape, floppy disk, optical data storage, and the like. Furthermore, the computer-readable recording media may be distributed across networked computer systems, such that the computer-readable code may be stored and executed in a distributed manner. And functional programs, code, and code segments for implementing the present disclosure can be readily deduced by programmers of ordinary skill in the art to which the present disclosure belongs.

One of ordinary skill in the art to which the present disclosure relates will understand that the disclosure may be implemented in modified form without departing from the essential features of the above description. The disclosed methods are therefore to be considered from an illustrative and not a limiting point of view. The scope of the invention is shown in the claims of the patent and not in the foregoing description, and all differences within that scope are to be construed as being included in the invention.

The invention claimed is:

1-10. (canceled)

11. A motor driving device comprising:
a first position detection sensor configured to detect a position of a motor and self-diagnose a defect;
a second position detection sensor configured to detect a position of the motor; and
a control unit configured to receive a position signal and a self-diagnosis signal from the first position detection sensor and receive a position signal from the second position detection sensor,
wherein the control unit determines whether the first position detection sensor is normal according to the self-diagnosis signal and, if the first position detection sensor is normal, determines whether the second position detection sensor is defective by using the position signal of the first position detection sensor.

12. The motor driving device of claim 11, wherein the position signal of the first position detection sensor and the position signal of the second position detection sensor have a predetermined phase difference.

13. The motor driving device of claim 11, wherein the control unit determines whether the second position detection sensor is defective by shifting a phase of the position signal of the first position detection sensor to a phase of the position signal of the second position detection sensor and comparing the position signal of the first position detection sensor with the position signal of the second position detection sensor.

14. The motor driving device of claim 11, comprising a third position detection sensor configured to detect a position of the motor,
wherein position signals of the first position detection sensor, the second position detection sensor, and the third position detection sensors have a phase difference of 120 degrees.

15. The motor driving device of claim 14, wherein the control unit uses the position signal of the first position detection sensor to determine whether the third position detection sensor is defective, and control the motor if all of the first position detection sensor, the second position detection sensor, and the third position detection sensors are normal.

16. The motor driving device of claim 11, wherein the first position detection sensor is an ASIL (AUTOMOTIVE SAFETY INTEGRITY LEVEL)-rated Hall sensor, and the second position detection sensor is a QM (QUALITY MANAGEMENT)-rated Hall sensor.

17. A motor driving device comprising:
a first Hall sensor;
a second Hall sensor having different ASIL (AUTOMOTIVE SAFETY INTEGRITY LEVEL) ratings from the first Hall sensor, and a third Hall sensor; and
a control unit configured to receive signals from the first Hall sensor, the second Hall sensor, and the third Hall sensors and control a motor,
wherein the control unit receives a position signal and a self-diagnosis signal from the first Hall sensor, and receives position signals from the second Hall sensor and the third Hall sensor to control the motor.

18. The motor driving device of claim 17, wherein the control unit determines whether the second hall sensor and the third hall sensor are defective by using the position signal of the first Hall sensor according to the self-diagnosis signal.

19. A motor driving method comprising:
determining whether a first position detection sensor is defective by using a self-diagnosis signal received from the first position detection sensor;
shifting a phase of a position signal received from the first position detection sensor to a phase of a position signal of a second position detection sensor, if the first position detection sensor is normal; and
determining whether the second position detection sensor is defective by comparing the phase of the position signal of the second position detection sensor with the phase of the position signal of the first position detection sensor.

20. The method of claim 19, wherein the first position detection sensor is an ASIL (AUTOMOTIVE SAFETY INTEGRITY LEVEL)-rated Hall sensor that detects a position of the motor, and the second position detection sensor is a QM (QUALITY MANAGEMENT)-rated Hall sensor that detects a position of the motor.

21. The motor driving device of claim 11, wherein the position signal is implemented as a pulse signal and the self-diagnosis signal is implemented as a tick signal.

22. The motor driving device of claim 21, wherein control unit receives a signal from the first position detection sensor, and determines that the first position detection sensor is normal if the signal received from the first position detection sensor has a tick signal.

23. The motor driving device of claim 21, wherein control unit receives a signal from the first position detection sensor, and determines that the first position detection sensor is defective if the signal received from the first position detection sensor does not have a tick signal.

24. The motor driving device of claim 21, wherein control unit receives a signal from the first position detection sensor, and determines that the first position detection sensor is defective if the signal received from the first position detection sensor does not have a tick signal for a predetermined time.

25. The motor driving device of claim 11, wherein the control unit controls an actuator driving the motor.

26. The motor driving device of claim 17, wherein the position signal is implemented as a pulse signal and the self-diagnosis signal is implemented as a tick signal.

27. The motor driving device of claim 26, wherein control unit receives a signal from the first Hall sensor, and determines that the first Hall sensor is normal if the signal received from the first Hall sensor has a tick signal.

28. The motor driving device of claim 26, wherein control unit receives a signal from the first Hall sensor, and determines that the first Hall sensor is defective if the signal received from the first Hall sensor does not have a tick signal.

29. The method of claim 19, wherein the position signal is implemented as a pulse and the self-diagnosis signal is implemented as a tick signal, and
wherein the first position detection sensor is determined as normal if a signal received from the first position detection sensor has a tick signal.

30. The method of claim 19, wherein the position signal is implemented as a pulse signal and the self-diagnosis signal is implemented as a tick signal, and
wherein the first position detection sensor is determined as defective if a signal received from the first position detection sensor does not have a tick signal.
